(19) United States
(12) Patent Application Publication
(10) Pub. No.: US 2020/0058573 A1
(43) Pub. Date: Feb. 20, 2020

(54) HEAT DISSIPATION STRUCTURE OF SEMICONDUCTOR DEVICE AND SEMICONDUCTOR DEVICE

(71) Applicant: DYNAX SEMICONDUCTOR, INC, KUNSHAN, JIANGSU PROVIN (CN)

(72) Inventors: Chuanjia WU, KUNSHAN, JIANGSU PROVIN (CN); Yi PEI, KUNSHAN, JIANGSU PROVINCE (CN)

(21) Appl. No.: 16/484,690

(22) PCT Filed: Aug. 7, 2018
(86) PCT No.: PCT/CN2018/099100

§ 371 Date: Aug. 8, 2019

(30) Foreign Application Priority Data
Aug. 8, 2017 (CN) 201710670923.1

(51) Int. Cl. H01L 23/42; H01L 23/373

(52) U.S. Cl. CPC H01L 23/42; H01L 23/3732; H01L 23/3738

(57) ABSTRACT

The present disclosure provides a heat dissipation structure of a semiconductor device and a semiconductor device, and it relates to a field of semiconductor technology. A heat dissipation structure of a semiconductor device according to an embodiment includes a first heat dissipation window formed on an upper surface of the heat dissipation structure at a side close to the semiconductor device, and at least one heat dissipation channel, the heat dissipation channel including an inflow channel and an outflow channel, transmitting a heat conducting medium to the first heat dissipation window via the inflow channel, the inflow channel including a first opening and a second opening, wherein the first opening is away from the first heat dissipation window, the second opening is close to the first heat dissipation window, and an opening area of the first opening is greater than an opening area of the second opening.

### CROSS REFERENCE TO RELATED APPLICATIONS

This patent application is a National Stage Entry of PCT/CN2018/099100 filed on Aug. 7, 2018, which claims the benefit and priority of Chinese Patent Application No. 201710670923.1 filed on Aug. 8, 2017, the disclosures of which are incorporated by reference herein in their entirety as part of the present application.

### BACKGROUND

Embodiments of the present disclosure relate to a field of semiconductor technology, and particularly relate to a heat dissipation structure of a semiconductor device and a semiconductor device.

With the maturity of GaN device technology, the advantages of high power density of GaN devices are more clearly demonstrated, and mass production of GaN devices begins in the industry. However, as the degree of integration of integrated circuits increases, higher demands are placed on the heat dissipation of GaN devices. According to measurements, the heat distribution of GaN devices is mainly concentrated near the Schottky junctions of the devices, and heat can be continuously generated. However, when the heat cannot be effectively dissipated, temperature of the Schottky junctions is raised, thereby reducing the power output and RF performance of the devices.

Traditional thermal management techniques are represented by remote cooling, such as thinning the substrate, adding metal heat sinks, and the like. The thermal performance of such technologies is very limited, which limits the power that a GaN device can output and make the power to be much lower than the power that can be output when the GaN device is sufficiently cooled, resulting in that the potential of the GaN device is not fully utilized and reducing the operating life of the GaN device.

### BRIEF DESCRIPTION

In view of this, embodiments of the present disclosure provide a heat dissipation structure of a semiconductor device and a semiconductor device, to solve the technical problem that the cooling effect of the semiconductor device is poor and the output power of the semiconductor device is low in the prior art.

In a first aspect, an embodiment of the present disclosure provides a heat dissipation structure of a semiconductor device, including a first heat dissipation window formed on an upper surface of the heat dissipation structure at a side close to the semiconductor device, and at least one heat dissipation channel, the heat dissipation channel including an inflow channel and an outflow channel, transmitting a heat conducting medium to the first heat dissipation window via the inflow channel, the inflow channel including a first opening and a second opening, wherein the first opening is away from the first heat dissipation window, the second opening is close to the first heat dissipation window, and an opening area of the first opening is greater than an opening area of the second opening.

Alternatively, the first opening is located on a lower surface of the heat dissipation structure.

Alternatively, the inflow channel and a center of the first heat dissipation window are aligned, and the outflow channel is located at two sides of the first heat dissipation window, or the outflow channel and the center of the first heat dissipation window are aligned, and the inflow channel is located at the two sides of the first heat dissipation window.

Alternatively, the cross-sectional shape of the inflow channel is a splayed shape or a step shape.

Alternatively, the material of the heat dissipation structure is stainless steel or silicon.

In a second aspect, an embodiment of the present disclosure provides a semiconductor device, including the heat dissipation structure above, and a substrate located at a side of the upper surface of the heat dissipation structure, a second heat dissipation window being formed in the substrate, vertical projection of the second heat dissipation window on a plane of the substrate and vertical projection of the first heat dissipation window on a plane of the substrate having an overlapping region, the second heat dissipation window and the first heat dissipation window forming a heat dissipation cavity.

Alternatively, the semiconductor device further includes a heat conducting layer located in the heat dissipation cavity, a nucleation layer located on the substrate, a buffer layer located at a side of the nucleation layer away from the substrate, a channel layer located at a side of the buffer layer away from the substrate, a barrier layer located at a side of the channel layer away from the substrate, wherein a two-dimensional electron gas is formed at an interface between the channel layer and the barrier layer, and a source, a gate, and a drain located at a side of the barrier layer away from the channel layer, wherein the gate is in Schottky contact with the barrier layer to form a Schottky junction.

Alternatively, a depth of the second heat dissipation window is smaller than or equal to a thickness of the substrate.

Alternatively, a third heat dissipation window is formed in the nucleation layer, vertical projection of the third heat dissipation window on the plane of the substrate and vertical projection of the second heat dissipation window on the plane of the substrate have an overlapping region, the third heat dissipation window, the second heat dissipation window, and the first heat dissipation window form a heat dissipation cavity.

Alternatively, a surface of the third heat dissipation window at a side close to the buffer layer ends in the nucleation layer, or is located at an interface between the nucleation layer and the buffer layer.

Alternatively, vertical projection of the Schottky junction on the plane of the heat conducting layer overlaps with the heat conducting layer.

Alternatively, vertical projection of the second heat dissipation window on the plane of the substrate completely overlaps with vertical projection of the first heat dissipation window on the plane of the substrate, and vertical projection of the third heat dissipation window on the plane of the substrate completely overlaps with vertical projection of the second heat dissipation window on the plane of the substrate.

Alternatively, a material of the heat conducting layer includes at least one of diamond, graphene, and boron nitride.

The heat dissipation structure of a semiconductor device and the semiconductor device provided by the embodiments of the present disclosure, by forming a first heat dissipation window on an upper surface at a side close to the semiconductor device, and transmitting a heat conducting medium to the first heat dissipation window via the inflow channel of the heat dissipation channel, while an area of the first opening of the inflow channel is greater than an area of the second opening of the inflow channel, ensure that the heat conducting medium flowing in through the inflow channel has a great outflow velocity at the second opening, ensure that the heat conducting medium is in sufficient contact with the semiconductor device, and the heat generated by the semiconductor device can be quickly dissipated, ensure a normal output power of the semiconductor device and increase the service life of the semiconductor device.

### BRIEF DESCRIPTION OF THE DRAWINGS

In order to illustrate the technical solutions of the exemplary embodiments of the present disclosure more clearly, drawings to be used in the embodiments will be briefly described below. Obviously, the drawings to be introduced are merely drawings of a part of embodiments to be described in the present disclosure other than all the drawings. Those ordinary skilled in the art can also obtain other related drawings according to these drawings without exercise of inventive skills.

FIG. 1 is a schematic structural diagram of a heat dissipation structure of a semiconductor device according to an embodiment of the present disclosure;

FIG. 2 is a schematic structural diagram of another heat dissipation structure of a semiconductor device according to an embodiment of the present disclosure;

FIG. 3 is a schematic structural diagram of yet another heat dissipation structure of a semiconductor device according to an embodiment of the present disclosure;

FIG. 4 is a schematic structural diagram of a semiconductor device according to an embodiment of the present disclosure; and

FIG. 5 is a schematic structural diagram of another semiconductor device according to an embodiment of the present disclosure.

### DETAILED DESCRIPTION

For better understanding of the technical solutions and advantages of the present disclosure, the technical solutions of the present disclosure are hereinafter described in detail with reference to the accompanying drawings in the embodiments of the present disclosure by using concrete performing forms. It is obvious that the described embodiments are just a part but not all of the embodiments of the present disclosure. Based on the embodiments of the present disclosure, all other embodiments obtained by those ordinary skilled in the art without exercise of inventive skills should be within the protection scope of the present disclosure.

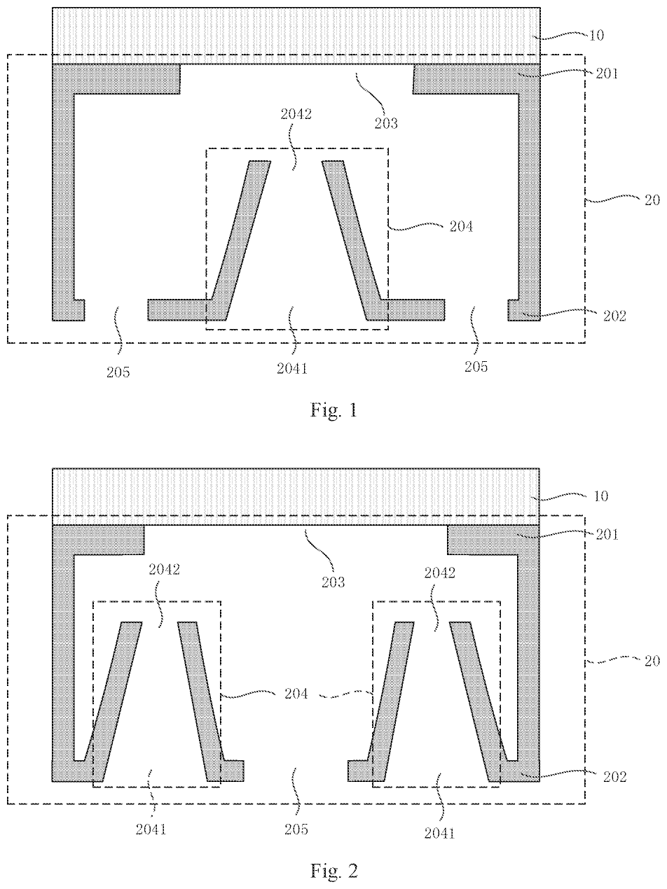

FIG. 1 is a schematic structural diagram of a heat dissipation structure of a semiconductor device according to an embodiment of the present disclosure. As shown in FIG. 1, the heat dissipation structure of a semiconductor device according to the embodiment of the present disclosure may include a first heat dissipation window 203 formed on an upper surface 201 of the heat dissipation structure 20 at a side close to the semiconductor device 10, and at least one heat dissipation channel, the heat dissipation channel including an inflow channel 204 and an outflow channel 205, transmitting a heat conducting medium to the first heat dissipation window via the inflow channel, the inflow channel 204 including a first opening 2041 and a second opening 2042, wherein the first opening 2041 is away from the first heat dissipation window, the second opening 2042 is close to the first heat dissipation window, and an opening area of the first opening 2041 is greater than an opening area of the second opening 2042.

Exemplarily, as shown in FIG. 1, the heat dissipation structure 20 is formed below the semiconductor device 10, where the upper surface 201 of the heat dissipation structure 20 is close to the semiconductor device 10, while the lower surface 202 of the heat dissipation structure 20 is away from the semiconductor device 10. Alternatively, the semiconductor device 10 may be a semiconductor device including a microwave integrated circuit, and specifically, it may further be an RF microwave integrated circuit including a gallium nitride (GaN)-based High Electron Mobility Transistor (HEMT) element. The heat dissipation structure 20 may further include a side surface surrounding the upper surface 201 and the lower surface 202, and the upper surface 201 and the lower surface 202 are joined by the side surface. Alternatively, the first heat dissipation window 203 is formed on the upper surface 201 of the heat dissipation structure 20, through which a heat conducting medium (not shown) located in the heat dissipation structure 20 contacts the semiconductor device 10 to absorb the heat generated by the semiconductor device 10. Alternatively, the heat conducting medium may be water or other heat conducting liquid or heat conducting gas. Alternatively, the first heat dissipation window 203 is disposed corresponding to the semiconductor device 10, and the semiconductor device 10 is exposed through the first heat dissipation window 203.

Alternatively, as shown in FIG. 1, the heat dissipation structure 20 may further include at least one heat dissipation channel which includes an inflow channel 204 and an outflow channel 205. The heat dissipation channel may be a circulation channel of the heat conducting medium which flows into the heat dissipation structure 20 through the inflow channel 204, contacts the semiconductor device 10 at a corresponding position of the first heat dissipation window 203, absorbs the heat generated by the semiconductor device 10, and then flows out of the heat dissipation structure 20 through the outflow channel 205. Alternatively, the inflow channel 204 may include two openings, i.e., a first opening 2041 and a second opening 2042. The heat conducting medium flows into the inflow channel 204 from the first opening 2041 and then flows into the heat dissipation structure 20 from the second opening 2042. The opening area of the first opening 2041 may be greater than the opening area of the second opening 2042. As such, the outflow velocity of the heat conducting medium flowing out of the second opening 2042 may be greater than the inflow velocity of the heat conducting medium flowing from the first opening 2041. Since the inflow channel 204 is disposed corresponding to the first heat dissipation window 203, as such, after flowing out from the second opening 2042, the heat conducting medium can quickly exchange heat with the semiconductor device 10, quickly absorb the heat generated by the semiconductor device 10, and ensure that the semiconductor device 10 can normally dissipate heat, ensure the normal output power of the semiconductor device 10 and increase the service life of the semiconductor device 10.

Alternatively, as shown in FIG. 1, the first opening 2041 may be located on a lower surface 202 of the heat dissipation structure 20, and the second opening 2042 is close to the first heat dissipation window 203. As such, the heat conducting medium flowing out of the second opening 2042 may directly absorb the heat generated by the semiconductor device 10. Alternatively, as shown in FIG. 1, the outflow channel 205 may be located around the inflow channel 204. The heat conducting medium flows into the inflow channel 204 through the first opening 2041 of the inflow channel 204, flows out from the second opening 2042 at a position close to the first heat dissipation window 203, and flows out of the heat-dissipating structure 20 through the outflow channel after exchanging heat with the semiconductor device 10 to ensure rapid circulation of the heat conducting medium.

Alternatively, as shown in FIG. 1, the heat dissipation structure 20 may include a plurality of outflow channels 205, which is illustrated in FIG. 1 with the heat dissipation structure 20 including two outflow channels 205 as an example. Alternatively, the inflow channel 204 may be located in the middle of the heat dissipation structure 20, and two outflow channels 205 may be located at two sides of the inflow channel 204, respectively. Two heat conducting channels are formed by that the heat conducting medium flows in through the inflow channel 204 and flows out through the two outflow channels 205, respectively, so as to ensure that the semiconductor device 10 may sufficiently dissipate heat.

Alternatively, FIG. 2 is a schematic structural diagram of another heat dissipation structure of a semiconductor device according to an embodiment of the present disclosure. The heat dissipation structure shown in FIG. 2 differs from the heat dissipation structure shown in FIG. 1 in including at least two inflow channels 204 and one outflow channel 205, which is illustrated in FIG. 2 only by including two inflow channels as an example. As shown in FIG. 2, two inflow channels 204 may be located at two sides of the heat dissipation structure 20, respectively, and the outflow channel 205 may be located in the middle of the heat dissipation structure 20. Two heat conducting channels are formed by that the heat conducting medium flows in through two inflow channels 204, respectively and flows out through the outflow channel 205, so as to ensure that the semiconductor device 10 may sufficiently dissipate heat. It should be noted that embodiments of the present disclosure do not limit the number and position of the inflow channel 204 and the outflow channel 205, and it suffices to form at least one heat dissipation channel, while it is ensured that the inflow channel 204 is disposed corresponding to the first heat dissipation window 203. The opening area of the first opening 2041 of the inflow channel 204 is greater than the opening area of the second opening 2042, which ensures that the heat conducting medium may flow through the semiconductor device 10 at a high flow velocity, and ensures rapid heat dissipation of the semiconductor device 10.

Alternatively, the inflow channel 204 of the heat dissipation channel may be connected to a heat conducting medium supply device (not shown) which outputs a heat conducting medium into the inflow channel 204. The outflow channel 205 of the heat dissipation channel may be connected to a heat conducting medium recovery device (not shown), and the heat conducting medium that has undergone heat exchange with the semiconductor device 10 is output to the heat conducting medium recovery device through the outflow channel 205.

Alternatively, as shown in FIG. 1 or FIG. 2, the cross-sectional shape of the inflow channel 204 may be a splayed shape. The first opening 2041 corresponds to a lower end of the splayed-shaped opening, and the second opening 2042 corresponds to an upper end of the splayed-shaped opening, ensuring that the opening area of the first opening 2041 is greater than the opening area of the second opening 2042.

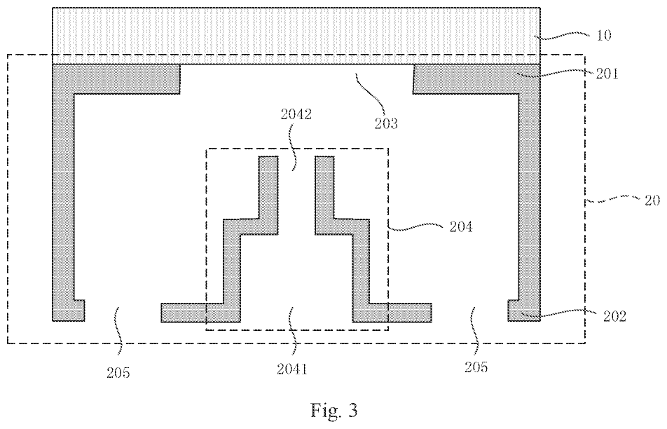

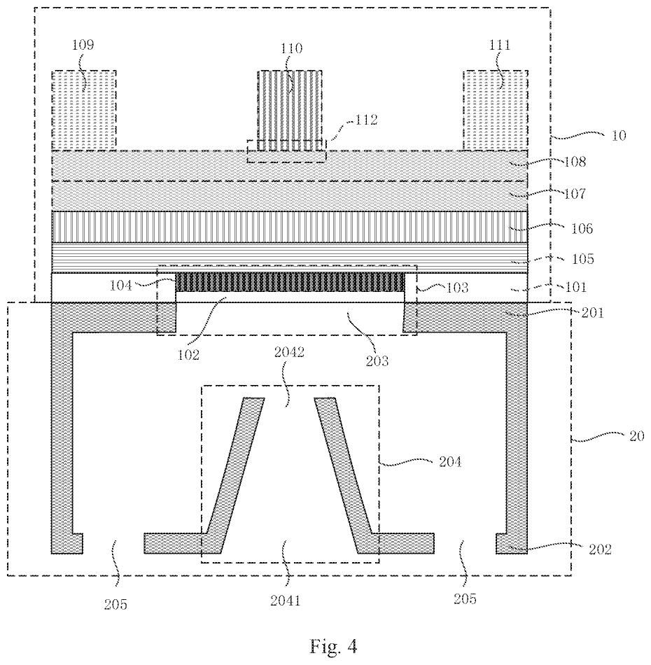

Alternatively, FIG. 3 is a schematic structural diagram of yet another heat dissipation structure of a semiconductor device according to an embodiment of the present disclosure. As shown in FIG. 3, the cross-sectional shape of the inflow channel 204 may be a step shape. The shape of the inflow channel 204 illustrated in FIG. 3 is not gradually narrowed from the first opening 2041 to the second opening 2042, but there is at least one varying step to ensure that the opening area of the first opening 2041 is greater than the opening area of the second opening 2042.

Alternatively, a material of the upper surface 202 and the lower surface 202 of the heat dissipation structure 20 and the heat dissipation channel is stainless steel or silicon.

In summary, the heat dissipation structure of a semiconductor device provided by the embodiments of the present disclosure, by forming a first heat dissipation window on an upper surface at a side close to the semiconductor device, and transmitting a heat conducting medium to the first heat dissipation window via the inflow channel of the heat dissipation channel, while an area of the first opening of the inflow channel is greater than an area of the second opening of the inflow channel, ensures that the heat conducting medium flowing in through the inflow channel has a great outflow velocity at the second opening, ensures that the heat conducting medium is in sufficient contact with the semiconductor device, the heat conducting medium can exchange heat with the semiconductor device sufficiently, and the heat generated by the semiconductor device can be quickly dissipated, ensures a normal output power of the semiconductor device and increases the service life of the semiconductor device.

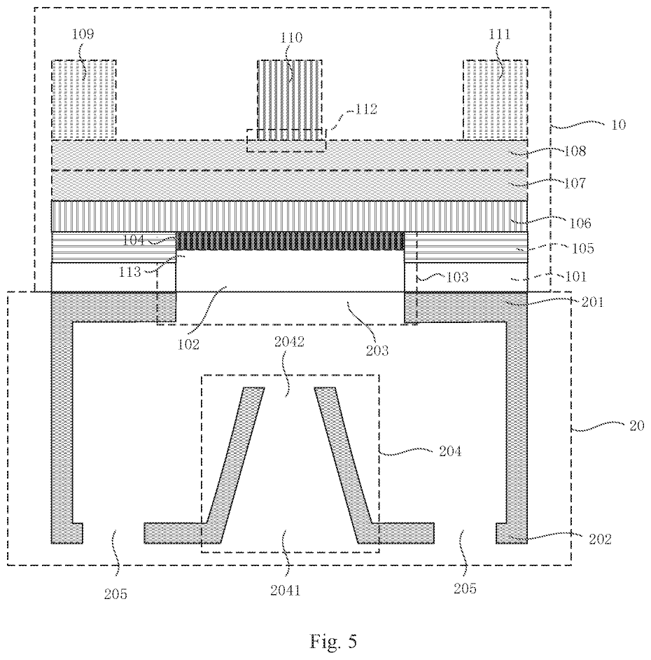

Alternatively, FIG. 4 is a schematic structural diagram of a semiconductor device according to an embodiment of the present disclosure. The semiconductor device according to the embodiment of the present disclosure includes the heat dissipation structure of a semiconductor device according to the embodiment mentioned above. Specifically, the semiconductor device according to the embodiment of the present disclosure may include the heat dissipation structure mentioned above, and a substrate 101 located at a side of the upper surface 201 of the heat dissipation structure 20, a second heat dissipation window 102 being formed in the substrate 101, vertical projection of the second heat dissipation window 102 on a plane of the substrate 101 and vertical projection of the first heat dissipation window 203 on a plane of the substrate 101 having an overlapping region, the second heat dissipation window 102 and the first heat dissipation window 203 forming a heat dissipation cavity 103.

Alternatively, the semiconductor device further includes a heat conducting layer 104 located in the heat dissipation cavity 103, a nucleation layer 105 located on the substrate 101, a buffer layer 106 located at a side of the nucleation layer 105 away from the substrate 101, a channel layer 107 located at a side of the buffer layer 106 away from the substrate 101, a barrier layer 108 located at a side of the channel layer 107 away from the substrate 101, wherein a two-dimensional electron gas is formed at an interface between the channel layer 107 and the barrier layer 108, and a source 109, a gate 110, and a drain 111 located at a side of the barrier layer 108 away from the channel layer 107, wherein the gate 110 is in Schottky contact with the barrier layer 108 to form a Schottky junction 112.

Exemplarily, as shown in FIG. 4, the semiconductor device 10 may include a substrate 101 at a side of the upper surface 201 of the heat dissipation structure 20, and a material of the substrate 101 may be silicon, silicon carbide, or sapphire, and may be other materials. A second heat dissipation window 102 is formed on the substrate 101. The second heat dissipation window 102 is disposed corresponding to the first heat dissipation window 203. Specifically, the vertical projection of the second heat dissipation window 102 on a plane of the substrate 101 and vertical projection of the first heat dissipation window 203 on a plane of the substrate 101 have an overlapping region; alternatively, it may be that the vertical projection of the second heat dissipation window 102 on a plane of the substrate 101 and vertical projection of the first heat dissipation window 203 on a plane of the substrate 101 completely overlap with each other, as shown in FIG. 4. Alternatively, further referring to FIG. 4, a depth of the second heat dissipation window 102 may be smaller than or equal to a thickness of the substrate 101, which means that a surface of the second heat dissipation window 102 close to the side of the nucleation layer 105 may end in the substrate 101, or be located at the interface between the substrate 101 and the nucleation layer 105. Alternatively, the substrate 101 may have a thickness of about 100 μm to 1000 μm, and the second heat dissipation window 102 may have a depth smaller than or equal to the thickness of the substrate 101. It should be noted that it is illustrated in FIG. 4 by taking that the depth of the second heat dissipation window 102 is equal to the thickness of the substrate 101 as an example. Alternatively, the first heat dissipation window 203 and the second heat dissipation window 102 together form a heat dissipation cavity 103. The heat conducting medium in the heat dissipation structure 20 exchanges heat with the semiconductor device 10 in the heat dissipation cavity 103 to absorb the heat generated by the semiconductor device 10 during the operation. Alternatively, when the vertical projection of the second heat dissipation window 102 on the plane of the substrate 101 completely overlaps with the vertical projection of the first heat dissipation window 203 on the plane of the substrate 101, the heat dissipation cavity 103 has a large area, which ensures that the heat conducting medium can sufficiently exchange heat with the semiconductor structure 10 to ensure that the heat of the semiconductor device 10 can be dissipated in time.

Alternatively, the heat conducting layer 104 is located within the heat dissipation cavity 103. As shown in FIG. 4, a heat conducting layer 104 is formed at a side of the nucleation layer 105 close to the substrate 101. The heat conducting layer 104 is located in the heat dissipation cavity 103 for conducting the heat generated by the semiconductor device 10. The heat conducting medium in the heat dissipation structure 20 absorbs the heat generated by the semiconductor device 10 by heat exchange with the heat conducting layer 104 in the heat dissipation cavity 103. Alternatively, the surface area of the heat conducting layer 104 may be as large as possible to ensure a large area for heat exchange. For example, the vertical projection of the heat conduction layer 104 on the plane of the substrate 101 may completely overlap with the vertical projection of the heat dissipation cavity 103 on the plane of the substrate 101 to ensure that the thermal conducting layer 104 may be completely formed in the heat dissipation cavity 103 to ensure that the heat generated by the semiconductor device 10 may be quickly dissipated. Alternatively, a material of the heat conducting layer 104 may be at least one of diamond, graphene, and boron nitride.

Alternatively, as shown in FIG. 4, the semiconductor device 10 may further include a nucleation layer 105 on the substrate 101. A material of the nucleation layer 105 may be a nitride, specifically GaN or AN or other nitride.

Alternatively, as shown in FIG. 4, the semiconductor device 10 may further include a buffer layer 106 on the nucleation layer 105. A material of the buffer layer 106 may be nitride, specifically GaN or AN or other nitride. The nucleation layer 105 and the buffer layer 106 may be used to match the material of the substrate 101 and the epitaxial channel layer 107.

Alternatively, as shown in FIG. 4, the semiconductor device 10 may further include a channel layer 107 on the buffer layer 106. A material of the channel layer 107 may be GaN or other semiconductor material, such as InAlN, which may be GaN here.

Alternatively, as shown in FIG. 4, the semiconductor device 10 may further include a barrier layer 108 at a side of the channel layer 107 away from the substrate 101. A two-dimensional electron gas is formed at an interface between the channel layer 107 and the barrier layer 108. A material of the barrier layer 108 may be AlGaN or other semiconductor material, such as InAlN, which may be AlGaN here. Alternatively, the channel layer 107 and the barrier layer 108 form a semiconductor heterojunction structure. A high concentration two-dimensional electron gas is formed at the interface of the channel layer 107 and the barrier layer 108, and a conducting channel is generated at the heterojunction interface of the channel layer 107.

Alternatively, as shown in FIG. 4, the semiconductor device 10 may further include a source 109, a gate 110, and a drain 111 at a side of the barrier layer 108 away from the channel layer 107. The source 109 and the drain 111 are located at both ends of the barrier layer 108, and the gate 110 is located between the source 109 and the drain 111. Alternatively, a material of the source 109 and the drain 111 may be one or a combination of more of metals such as Ni, Ti, Al, and Au, and the source 109 and the drain 111 are in ohmic contact with the barrier layer 108, and a material of the gate 110 may be one or a combination of more of metals such as Ni, Pt, Pb, and Au, and the gate 110 is in Schottky contact with the barrier layer 108 to form a Schottky junction 112. Alternatively, the heat of the semiconductor device 10 is mainly concentrated near the Schottky junction 112. The heat generated by the Schottky junction 112 may be conducted to the position of the heat dissipation cavity 103 through the heat conducting layer 104, and the heat generated by the Schottky junction 112 is absorbed by heat exchange with the heat conducting medium at the position of the heat dissipation cavity 103 to ensure that the semiconductor device 10 can dissipate heat and ensure the normal operation of the semiconductor device 10. Alternatively, the Schottky junction 112 may be disposed corresponding to the heat conducting layer 104, and specifically, the vertical projection of the Schottky junction 112 on the plane of the heat conducting layer 104 may overlap with the heat conducting layer 104 to ensure that the heat generated by the Schottky junction 112 may be conducted out directly through the heat conducting layer 104, ensure that the semiconductor device 10 does not cause a drop in output power due to excessive temperature, and ensure normal operation of the semiconductor device 10.

In summary, the semiconductor device provided by the embodiment of the present disclosure, including the heat dissipation structure of a semiconductor device according to the embodiments above of the present disclosure, by forming a second heat dissipation window on the substrate of the semiconductor device, the second heat dissipation window being disposed corresponding to the first heat dissipation window in the heat dissipation structure to form a heat dissipation cavity, where the heat conducting medium flowing in through the heat dissipation channel of the heat dissipation structure exchanges heat with the heat conducting layer in the heat dissipation cavity and conducts the heat generated by the semiconductor device to the heat conducting medium, ensures that the heat conducting medium is in sufficient contact with the semiconductor device, where the heat conducting medium can exchange heat with the semiconductor device sufficiently and the heat generated by the semiconductor device can be quickly dissipated, and ensures a normal output power of the semiconductor device.

Alternatively, FIG. 5 is a schematic structural diagram of another semiconductor device according to an embodiment of the present disclosure. The semiconductor device shown in FIG. 5 is improved on the basis of the semiconductor device described in the above embodiment. Specifically, the semiconductor device in FIG. 5 has a third window formed on the nucleation layer, referring to FIG. 5:

A third heat dissipation window 113 is formed in the nucleation layer 105. The third heat dissipation window 113 is disposed corresponding to the second heat dissipation window 102. Specifically, the vertical projection of the third heat dissipation window 113 on the plane of the substrate 101 and the vertical projection of the second heat dissipation window 102 on the plane of the substrate 101 have an overlapping region. Alternatively, the surface at a side of the third heat dissipation window 113 close to the buffer layer 106 ends in the nucleation layer 105 or is located at the interface between the nucleation layer 105 and the buffer layer 106, to ensure that a depth of the third heat dissipation window 113 is smaller than or equal to a thickness of the nucleation layer 105, which is illustrated in FIG. 5 only by taking that the depth of the third heat dissipation window 113 equal to the thickness of the nucleation layer 105 as an example. Specifically, in the existing preparation process of the semiconductor device, a low-temperature nucleation layer 105 is deposited on the substrate 101 at first, followed by a low-temperature grown nucleation layer 105, where the nucleation layer 105 has many crystal defects, and usually contains a mixed crystal system such as cubic and hexagonal ones, so that the heat conductivity thereof is poor, and the heat generated at the Schottky junction 112 cannot be completely conducted to the heat conducting layer 104. Therefore, a third heat dissipation window 113 is formed on the nucleation layer 105, the third heat dissipation window 113, together with the second heat dissipation window 102 and the first heat dissipation window 203, forming a heat dissipation cavity 103 in which the heat conducting layer 104 is located and directly contacts the barrier layer 108 to ensure that the heat generated by the Schottky junction 111 may be conducted to the heat conducting layer 104, thereby performing heat exchange with the heat conducting medium, to ensure that the heat generated by the Schottky junction 112 can be conducted out of the semiconductor device 10 in time.

Alternatively, the vertical projection of the third heat dissipation window 113 on the plane of the substrate 101 completely overlaps with the vertical projection of the second heat dissipation window 102 on the plane of the substrate 101, as shown in FIG. 5. The third heat dissipation window 113, the second heat dissipation window 102, and the first heat dissipation window 203 together form a heat dissipation cavity 103. The heat conducting medium in the heat dissipation structure 20 exchanges heat with the semiconductor device 10 in the heat dissipation cavity 103 to absorb the heat generated by the semiconductor device 10 during operation. Alternatively, when the vertical projection of the third heat dissipation window 113 on the plane of the substrate 101 completely overlaps with the vertical projection of the second heat dissipation window 102 on the plane of the substrate 101, the heat dissipation cavity 203 has a larger area, which ensures that the heat conducting medium may exchange heat with the semiconductor structure 10 sufficiently, and ensures that the heat of the semiconductor device 10 may be dissipated in time.

In summary, the semiconductor device provided by the embodiment of the present disclosure, by forming a third heat dissipation window on the nucleation layer, forming a second heat dissipation window on the substrate, where the third heat dissipation window and the second heat dissipation window are disposed corresponding to the first heat dissipation window in the heat dissipation structure, and together form a heat dissipation cavity, and the heat conducting medium exchanges heat with the heat conducting layer in the heat dissipation cavity and conducts the heat generated by the semiconductor device to the heat conducting medium, ensures that the heat conducting medium is in sufficient contact with the semiconductor device, where the heat conducting medium can exchange heat with the semiconductor device sufficiently and the heat generated by the semiconductor device can be quickly dissipated, and ensures a normal output power of the semiconductor device.

It should be noted that the above is only example embodiments of the present disclosure and the technical principles applied thereto. Those skilled in the art will appreciate that the present disclosure is not limited to the specific embodiments described herein, and those skilled in the art can make various obvious variations, readjustments, combinations, and substitutions without departing from the scope of the present disclosure. Therefore, although the present disclosure has been described in detail by the above embodiments, it is not limited only to the above embodiments. The present disclosure may include more other equivalent embodiments without departing from the inventive concept. The scope of the disclosure is determined by the scope of the appended claims.

1. A heat dissipation structure of a semiconductor device, the structure comprising:
a first heat dissipation window formed on an upper surface of the heat dissipation structure at a side close to the semiconductor device; and
at least one heat dissipation channel, the at least one heat dissipation channel including an inflow channel and an outflow channel, the at least one heat dissipation channel transmitting a heat conducting medium to the first heat dissipation window via the inflow channel, the inflow channel including a first opening and a second opening, wherein the first opening is away from the first heat dissipation window and located on a lower surface of the heat dissipation structure, the second opening is close to the first heat dissipation window and away from the lower surface of the heat dissipation structure, and an opening area of the first opening is greater than an opening area of the second opening.

2. (canceled)

3. The heat dissipation structure according to claim 1, wherein i) the inflow channel and a center of the first heat dissipation window are aligned, and the outflow channel is located at two sides of the first heat dissipation window, or ii) the outflow channel and the center of the first heat dissipation window are aligned, and the inflow channel is located at the two sides of the first heat dissipation window.

4. The heat dissipation structure according to claim 1, wherein the cross-sectional shape of the inflow channel is one of a splayed shape and a step shape.

5. The heat dissipation structure according to claim 1, wherein the material of the heat dissipation structure is one of stainless steel and silicon.

6. A semiconductor device comprising:
the heat dissipation structure according to claim 1; and
a substrate located at a side of the upper surface of the heat dissipation structure, a second heat dissipation window formed in the substrate, vertical projection of the second heat dissipation window on a plane of the substrate and vertical projection of the first heat dissipation window on a plane of the substrate having an overlapping region, the second heat dissipation window and the first heat dissipation window forming a heat dissipation cavity.

7. The semiconductor device according to claim 6, further comprising:
a heat conducting layer located in the heat dissipation cavity;
a nucleation layer located on the substrate;
a buffer layer located at a side of the nucleation layer away from the substrate;
a channel layer located at a side of the buffer layer away from the substrate;
a barrier layer located at a side of the channel layer away from the substrate, wherein a two-dimensional electron gas is formed at an interface between the channel layer and the barrier layer; and
a source, a gate, and a drain located at a side of the barrier layer away from the channel layer, wherein the gate is in Schottky contact with the barrier layer to form a Schottky junction.

8. The semiconductor device according to claim 6, wherein a depth of the second heat dissipation window is smaller than or equal to a thickness of the substrate.

9. The semiconductor device according to claim 7, wherein a third heat dissipation window is formed in the nucleation layer, wherein vertical projection of the third heat dissipation window on the plane of the substrate and vertical projection of the second heat dissipation window on the plane of the substrate have an overlapping region, and wherein the third heat dissipation window, the second heat dissipation window, and the first heat dissipation window form a heat dissipation cavity.

10. The semiconductor device according to claim 9, wherein a surface of the third heat dissipation window at a side close to the buffer layer ends in the nucleation layer, or is located at an interface between the nucleation layer and the buffer layer.

11. The semiconductor device according to claim 7, wherein vertical projection of the Schottky junction on the plane of the heat conducting layer overlaps with the heat conducting layer.

12. The semiconductor device according to claim 9, wherein vertical projection of the second heat dissipation window on the plane of the substrate completely overlaps with vertical projection of the first heat dissipation window on the plane of the substrate, and wherein vertical projection of the third heat dissipation window on the plane of the substrate completely overlaps with vertical projection of the second heat dissipation window on the plane of the substrate.

13. The semiconductor device according to claim 7, wherein a material of the heat conducting layer includes at least one of diamond, graphene, and boron nitride.

14. The heat dissipation structure according to claim 1, wherein vertical projection of the first opening on a plane of the first heat dissipation window has an overlapping region with the first heat dissipation window, and wherein vertical projection of the second opening on the plane of the first heat dissipation window has an overlapping region with the first heat dissipation window.

15. The heat dissipation structure according to claim 1, wherein the heat dissipation channel includes at least one outflow channel, and wherein the opening area of the first opening is greater than an area of one of the at least one outflow channel.

16. The heat dissipation structure according to claim 1, wherein the outflow channel includes a third opening and a fourth opening, wherein the third opening is close to the first heat dissipation window and located on a same plane with the second opening, and wherein an opening area of the second opening is lower than an opening area of the third opening.
